(19) United States
(12) Patent Application Publication
(10) Pub. No.: US 2008/0080273 A1
(43) Pub. Date: Apr. 3, 2008

(54) Over-drive control signal generator for use in semiconductor memory device

(75) Inventor: Khil-Ock Kang, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/824,381

(22) Filed: Jun. 29, 2007

(30) Foreign Application Priority Data
Oct. 2, 2006 (KR) 2006-0096959

(51) Int. Cl. G11C 7/00; G11C 7/02

(52) U.S. Cl. 365/194; 365/207; 365/222

(57) ABSTRACT

An over-drive control signal generator for use in a semiconductor memory device includes a delay control unit and a pulse generation unit. The delay control unit delays a bit line sense amplifier (BLSA) enable signal for a first delay time in response to an auto refresh signal to thereby output a delayed BLSA enable signal. The pulse generation unit generates an over-drive control signal having a pulse length corresponding to an over-drive time by delaying the delayed BLSA enable signal for a second delay time in response to the BLSA enable signal.

### CROSS-REFERENCE TO RELATED APPLICATION

The present invention claims priority of Korean patent application number 10-2006-0096959, filed on Oct. 2, 2006, which is incorporated by reference in its entirety.

### BACKGROUND OF THE INVENTION

The present invention relates to a semiconductor memory device, and more particularly to an over-drive control signal generator for controlling an over-drive operation of a semiconductor memory device.

As a minimum line width has decreased and a scale of integration of a semiconductor memory device has increased, a voltage level of a power supply voltage used in the semiconductor memory device has decreased. Presently, most of the semiconductor memory devices internally provide an internal voltage having a low voltage level by including an internal voltage generator. The internal voltage generator generates the internal voltage of low voltage level from an external voltage having relatively high voltage level; and the internal voltage is used for processing operations of internal elements included the semiconductor memory device. Particularly, a dynamic random access memory (DRAM), a kind of the semiconductor memory device, generates and uses a core voltage in order to sense a cell data.

The DRAM includes a plurality of bit line sense amplifiers (BLSA) for sensing the cell data. In detail, when a word line is activated in response to a corresponding row address, the data in a plurality of memory cells connected to the word line are transmitted to corresponding bit lines. Each of the BLSAs senses and amplifies a voltage difference between corresponding bit line pairs driven by the core voltage. Herein, about thousands of BLSAs are operated at the same time and, thus, a large amount of the core voltage is consumed. As above mentioned, because the voltage level of the core voltage is lower, it is not adequate to amplify numerous cell data in a short time.

In order to solve the abovementioned problem, the BLSAs are driven through an over-driving method. That is, the BLSAs are driven with a voltage having a higher voltage level than the core voltage for a predetermined time at an initial operation period of the BLSAs. Usually, the voltage is a power supply voltage VDD.

FIG. 1 is a schematic circuit diagram of conventional BLSA unit employing the over-driving method.

The conventional BLSA unit includes an upper bit line isolator 10, a bit line equalizing/precharging unit 20, a BLSA 30, a column selector 40, a lower bit line isolator 50, and a BLSA driver 60.

The upper and the lower bit line isolators 10 and 50 disconnect or connect the BLSA 30 with corresponding memory cell array in response to an upper isolation signal BISH and a lower isolation signal BISL, respectively. The BLSA 30 senses a voltage difference between a bit line pair BL and BLB and amplifies one of the bit line pair BL and BLB as a ground voltage VSS level and the other as the core voltage VCORE level when a pull down power line SB and a pull up power line RTO are driven to a predetermined voltage level. The bit line equalizing/precharging unit 20 precharges the bit line pair BL and BLB as a precharge voltage VBLP level in response to a bit line equalization signal BLEQ. Usually, the bit line precharge voltage VBLP has a half voltage level of the core voltage level. The column selector 40 transmits a cell data amplified by the BLSA 30 to a segment data bus SIO and SIOB in response to a column selection signal YI. The column selection signal YI is activated in response to a read command. The BLSA driver 60 drives the pull up power line RTO and the pull down power line SB with the power supply voltage VDD, the core voltage VCORE, and the ground voltage VSS.

The BLSA driver 60 includes two PMOS transistors M1 and M2, a NMOS transistor M3, and a BLSA power line equalizing/precharging unit 62. The first PMOS transistor M1 drives the pull up power line RTO with the power supply voltage VDD in response to an over-drive control signal SAOVDP. The first PMOS transistor M1 operates as an over-driver. The second PMOS transistor M2 drives the pull up power line RTO with the core voltage VCORE in response to a pull up drive control signal SAP. The NMOS transistor M3 drives the pull down power line SB with the ground voltage VSS in response to a pull down drive control signal SAN. The BLSA power line equalizing/precharging unit 62 precharges the pull up power line RTO and the pull down power line SB as the precharge voltage VBLP level in response to the bit line equalization signal BLEQ. In other embodiments, the first and the second PMOS transistors M1 and M2 can be replaced with NMOS transistors; and the NMOS transistor M3 can be replaced with a PMOS transistor.

FIG. 2 is a block diagram of an over-drive control signal generator for generating the over-drive control signal SAOVDP.

The over-drive control signal generator includes an enable signal generator 200, an over-drive pulse generator 210, and a power line drive signal generator 220. The enable signal generator 200 generates a BLSA enable signal SAEN in response to an active command ACT and a precharge command PCG. The over-drive pulse generator 210 generates the over-drive control signal SAOVDP based on the BLSA enable signal SAEN. The power line drive signal generator 220 generates the pull up drive control signal SAP and the pull down drive control signal SAN based on the BLSA enable signal SAEN.

FIG. 3 is a schematic circuit diagram of the over-drive pulse generator 210 shown in FIG. 2.

The over-drive pulse generator 210 includes a delay 212, a first inverter INV1, and a first NAND gate NDND1. The delay 212 delays the BLSA enable signal SAEN for a predetermined time. The first inverter INV1 inverts an output of the delay 212. The first NAND gate NAND1 logically combines the BLSA enable signal SAEN and an output of the first NAND gate NAND1 to thereby outputs the over-drive control signal SAOVDP.

FIG. 4 is a waveform illustrating an operation of the over-drive control signal generator shown in FIG. 2.

After a predetermined time from input of the active command ACT, the pull up drive control signal SAP is activated as a logic low level and the pull down drive control signal SAN is activated as a logic high level. Herein, the over-drive control signal SAOVDP is activated as a logic low level in response to the active command ACT before or at least same time the pull up drive control signal SAP and the pull down drive control signal SAN are activated. The pull up power line RTO is over-driven according to the activated over-drive control signal SAOVDP. That is, when all of the pull up drive control signal SAP, the pull down drive control signal SAN, and the over-drive control signal SAOVDP are activated, the MOS transistors M1 to M3 shown in FIG. 1 are turned on. Therefore, the pull up power line RTO is driven with the power supply voltage VDD and the pull down power line SB is driven with the ground voltage VSS.

When the over-drive control signal is inactivated as a logic high level, the pull up power line RTO is driven with the core voltage VCORE. After the precharge command PCG is input, the pull up drive control signal SAP and the pull down drive control signal SAN are inactivated and the pull up power line RTO and the pull down power line SB are precharged as the precharge voltage VBLP level. As above mentioned, the precharge voltage VBLP usually has the half voltage level of the core voltage VCORE.

Meanwhile, data stored in the DRAM eventually fades unlike other semiconductor memory devices such as static random access memory (SRAM) and flash memory. Therefore, the DRAM is required to be rewritten the data periodically. The rewriting operation is referred as a refresh operation. The refresh operation is performed by sensing and amplifying cell data and rewriting the amplified cell data at least once during a retention time of the cell data.

There are two operation modes of the refresh operation. The one is an auto refresh mode for performing the refresh operation during a normal operation by generating internal addresses in response to a certain command. The other is a self refresh mode for performing the refresh operation during a stand-by mode, e.g., a power down mode. During the auto refresh mode, a chipset provides cell capacitor with charge as much as lost by leakage of the cell capacitor. In case that the DRAM performs the refresh operation in the auto refresh mode, the number of word lines which are activated is numerous and, therefore, the voltage level of the core voltage VCORE is dramatically decreased.

FIG. 5 is a waveform describing a simulation result of a conventional over-driving circuit including the over-drive control signal generator shown in FIG. 2. Herein, it is presumed that the voltage level of the power supply voltage VDD is about 1.6 V and the voltage level of the core voltage VCORE is about 1.5 V.

As shown, the voltage level of the core voltage VCORE in an active mode is stable and, thus, an over-drive operation can be performed appropriately. Meanwhile, it is easily noticed that the voltage level of the core voltage VCORE is dramatically decreased during the auto refresh mode. While single word line is activated in response to the active command ACT during the active mode, several word lines are activated at the same time in response to an auto refresh command for the auto refresh mode. Therefore, the voltage level of the core voltage VCORE is abruptly decreased for the auto refresh mode. In this case, because of unstable voltage level of the core voltage VCORE, the operation of the semiconductor memory device can be deteriorated and, further, the semiconductor memory device operates incorrectly.

In order to solve the problem caused by the abrupt decrease of the core voltage VCORE, it can be considered to increase an over-drive operation time for the auto refresh mode. In this case, however, the voltage level of the core voltage VCORE excessively increases for the active mode.

### SUMMARY OF THE INVENTION

Embodiments of the present invention are directed to provide an over-drive control signal generator for generating an over-drive control signal in order to provide a stable normal drive voltage for an auto refresh mode as well as an active mode.

In accordance with an aspect of the present invention, there is provided an over-drive control signal generator for use in a semiconductor memory device including a delay control unit and a pulse generation unit. The delay control unit delays a bit line sense amplifier (BLSA) enable signal for a first delay time in response to an auto refresh signal to thereby output a delayed BLSA enable signal. The pulse generation unit generates an over-drive control signal having a pulse length corresponding to an over-drive time by delaying the delayed BLSA enable signal for a second delay time in response to the BLSA enable signal. The second delay time corresponds to an over-drive time required for an active mode. The first delay time corresponds to a time subtracting the over-drive time required for the active mode from the over-drive time required for an auto refresh mode.

In accordance with another aspect of the present invention, there is provided a method for controlling an over-drive operation of a semiconductor memory device including generating an over-drive control signal having a pulse length corresponding to a predetermined delay time in response to a bit line sense amplifier (BLSA) enable signal for an active mode; generating the over-drive control signal having a pulse length longer than the predetermined delay time in response to the BLSA enable signal for an auto refresh mode; and performing the over-drive operation in response to the over-drive control signal.

In accordance with still another aspect of the present invention, there is provided a method for controlling an over-drive operation of a semiconductor memory device including performing a delay operation to a bit line sense amplifier (BLSA) enable signal for a first delay time in response to an auto refresh signal to thereby generate a delayed BLSA enable signal; generating an over-drive control signal having a pulse length corresponding to an over-drive time by delaying the delayed BLSA enable signal for a second delay time in response to the BLSA enable signal; and performing the over-drive operation in response to the over-drive control signal. The second delay time corresponds to an over-drive time required for an active mode. The first delay time corresponds to a time subtracting the over-drive time required for the active mode from the over-drive time required for an auto refresh mode.

### BRIEF DESCRIPTION OF THE DRAWINGS

FIG. 1 is a schematic circuit diagram of conventional BLSA unit employing an over-driving method.

FIG. 2 is a block diagram of an over-drive control signal generator for generating an over-drive control signal SAOVDP.

FIG. 3 is a schematic circuit diagram of an over-drive pulse generator shown in FIG. 2.

FIG. 4 is a waveform illustrating an operation of the over-drive control signal generator shown in FIG. 2.

FIG. 5 is a waveform describing a simulation result of a conventional over-driving circuit including the over-drive control signal generator shown in FIG. 2.

FIG. 6 is a block diagram of an over-drive control signal generator in accordance with an embodiment of the present invention.

FIG. 7 is a schematic circuit diagram of the over-drive control signal generator shown in FIG. 6.

FIG. 8 is a waveform describing a simulation result of an over-driving circuit including the over-drive control signal generator shown in FIG. 7.

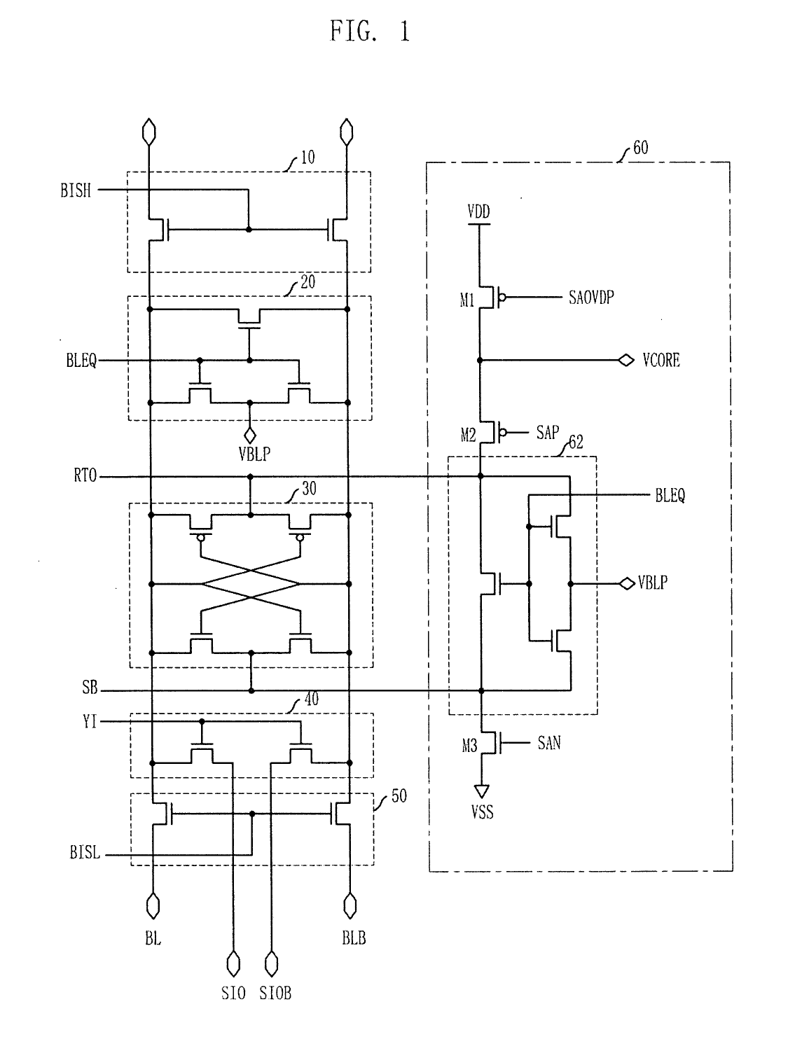

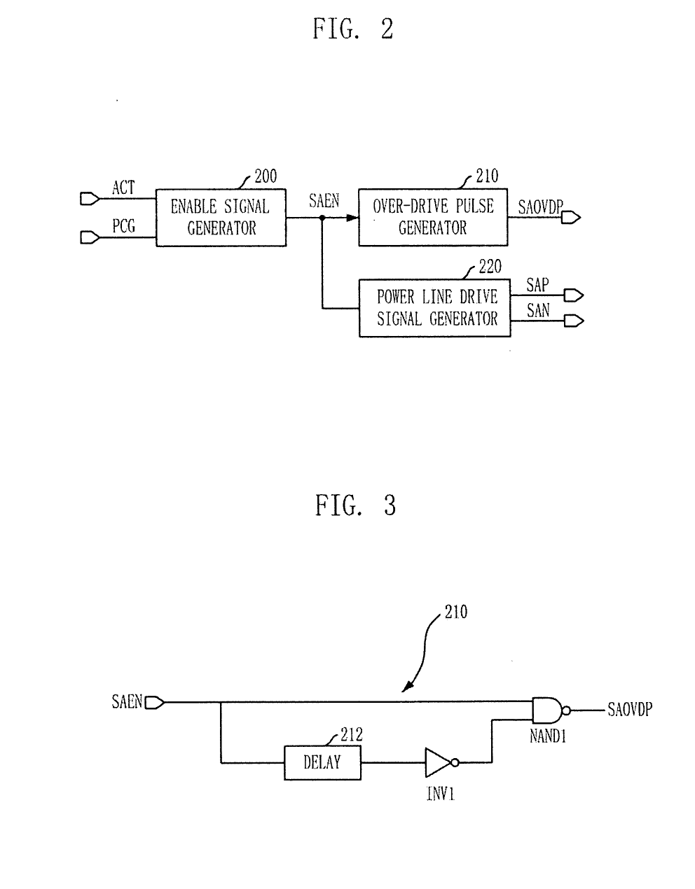

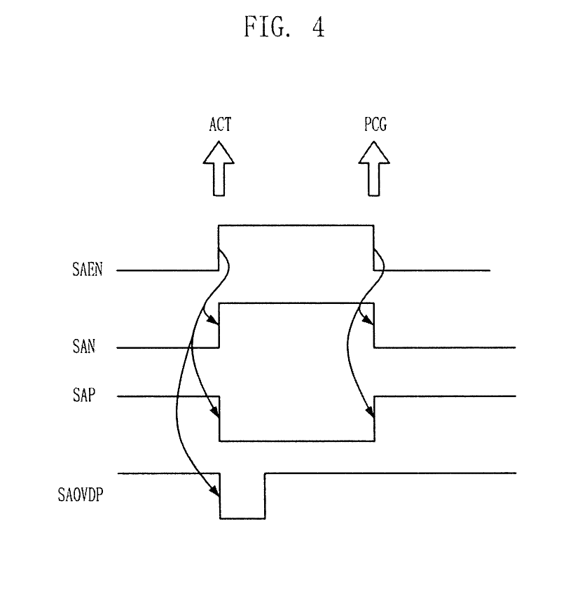

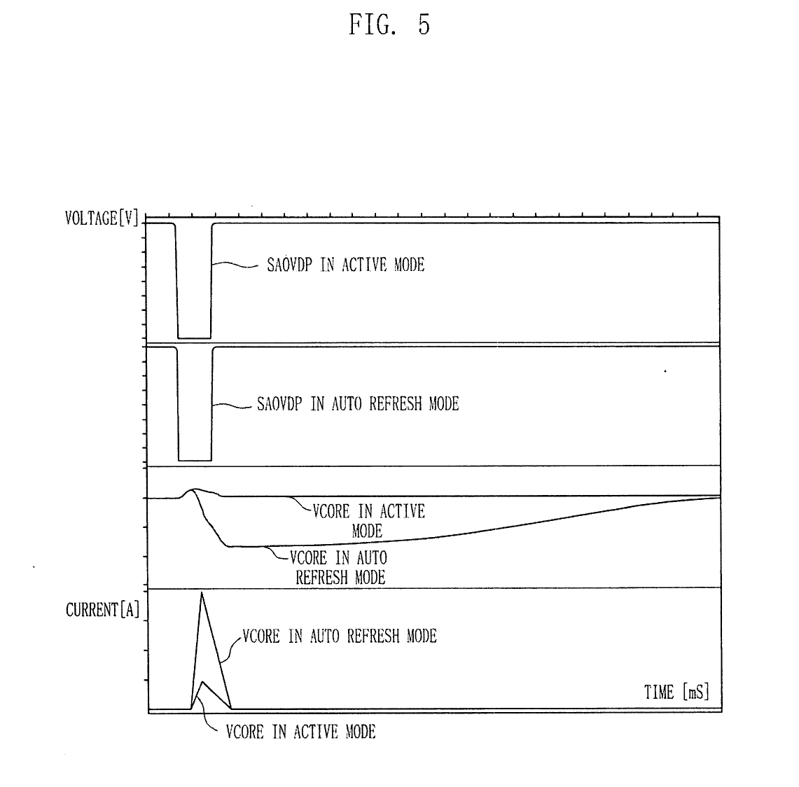

### DESCRIPTION OF SPECIFIC EMBODIMENTS

The present invention provides an over drive control circuit for controlling a voltage level of the core voltage VCORE so that it is stable in the auto refresh mode as well as the active mode.

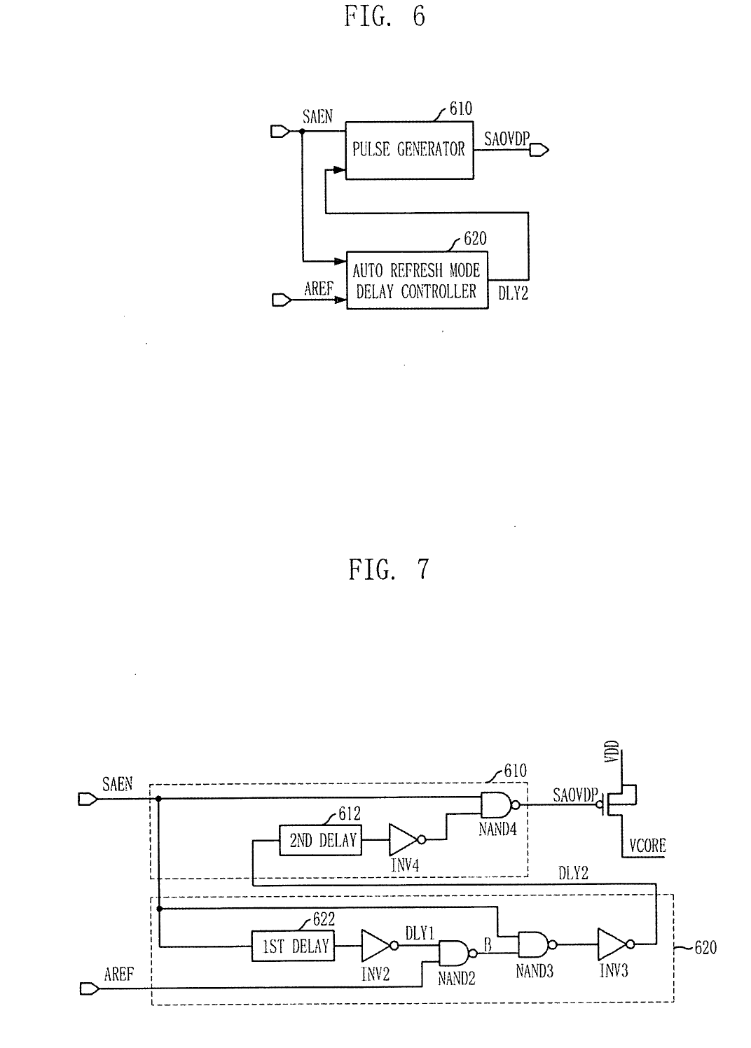

FIG. 6 is a block diagram of an over-drive control signal generator in accordance with an embodiment of the present invention.

The over-drive control signal generator includes a pulse generator 610 and an auto refresh mode delay controller 620. The auto refresh mode delay controller 620 delays a bit line sense amplifier (BLSA) enable signal SAEN for a predetermined time in response to an auto refresh signal AREF. The pulse generator 610 generates an over-drive control signal SAOVDP in response to the BLSA enable signal SAEN and an output signal DLY2 of the auto refresh mode delay controller 620. The over-drive control signal SAOVDP has a pulse length corresponding to an over-drive time.

FIG. 7 is a schematic circuit diagram of the over-drive control signal generator shown in FIG. 6.

The auto refresh mode delay controller 620 includes a first delay 622, two inverters INV2 and INV3, and two NAND gates NAND2 and NAND3. The first delay 622 delays the BLSA enable signal SAEN. The second inverter INV2 inverts an output of the first delay 622. The second NAND gate NAND2 logically combines an output DLY1 of the second inverter INV2 and the auto refresh signal AREF. The third NAND gate NAND3 logically combines an output B of the second NAND gate NAND2 and the BLSA enable signal SAEN. The third inverter INV3 inverts an output of the third NAND gate NAND3 to thereby output the output signal DLY2. The pulse generator 610 includes a second delay 612, a fourth inverter INV4, and a fourth NAND gate NAND4. The second delay 612 delays the output signal DLY2 of the auto refresh mode delay controller 620. The fourth inverter INV4 inverts an output of the second delay 612. The fourth NAND gate NAND4 logically combines an output A of the fourth inverter INV4 and the BLSA enable signal SAEN and outputs the over-drive control signal SAOVDP. Herein, a delay length of the second delay 612 corresponds to an over-drive time required for the active mode. A delay length of the first delay 622 corresponds to a time subtracting the over-drive time required for the active mode from an over-drive time required for the auto refresh mode.

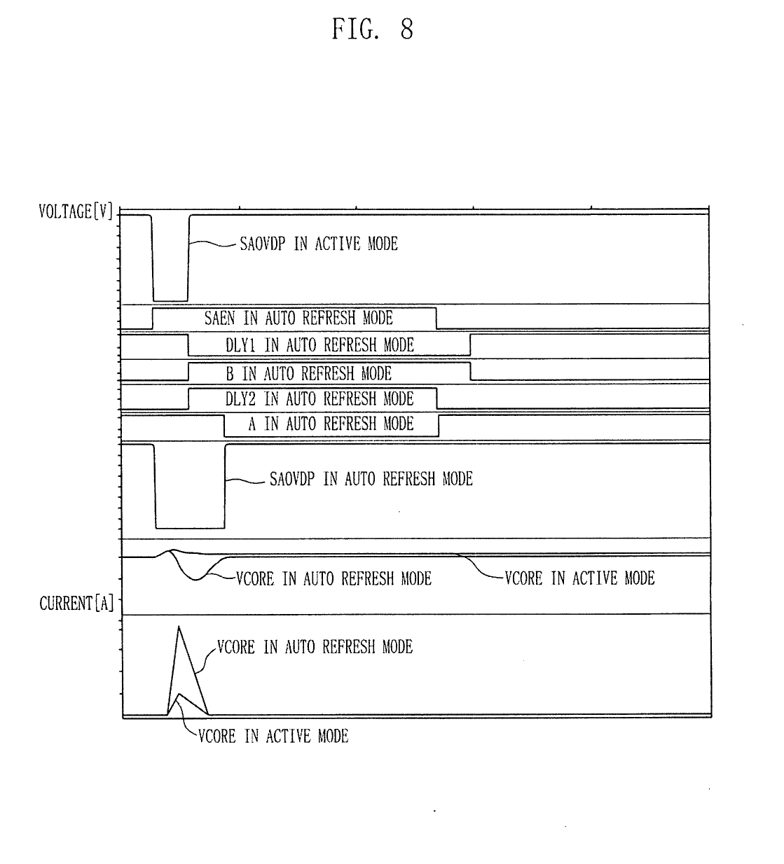

FIG. 8 is a waveform describing a simulation result of an over-driving circuit including the over-drive control signal generator shown in FIG. 7. It is presumed that a voltage level of a power supply voltage VDD is about 1.6V and a voltage level of a core voltage VCORE is about 1.5V.

When the semiconductor memory device is in the active mode, the auto refresh signal AREF has a logic low level. Accordingly, the second NAND gate NAND2 blocks the delayed BSLA enable signal SAEN, transmitted through the first delay 622 and the second inverter INV2, in response to the auto refresh signal AREF. That is, the second NAND gate NAND2 outputs the output B of a logic high level. The third NAND gate NAND3 and the third inverter INV3 transmits the BLSA enable signal SAEN which is not delayed as the output signal DLY2. When propagation delays of the third NAND gate NAND3 and the third inverter INV3 are ignored, the output signal DLY2 of the auto refresh mode delay controller 620 has substantially the same phase with the BLSA enable signal SAEN. As a result, the pulse generator 610 outputs the over-drive control signal SAOVDP having a pulse length corresponding to the delay length of the second delay 612.

When the semiconductor memory device is in the auto refresh mode, the auto refresh signal AREF is active as a logic high level. The second NAND gate NAND2 outputs the delayed BLSA enable signal SAEN as the output B. The output B is output as the output signal DLY2 through the third NAND gate NAND3 and the third inverter INV3. That is, the output signal DLY2 lags behind the BLSA enable signal as much as the delay length of the first delay 622. When propagation delays of the inverters INV2 to INV4 and the NAND gates NAND2 to NAND4 are ignored, the pulse generator 610 outputs the over-drive control signal SAOVD having a pulse length produced by adding the delay length of the first delay 622 to the delay length of the second delay 612.

As above described, the over-drive time for the auto refresh mode is increased and, thus, more current is provided to a core voltage VCORE terminal compared with the conventional art. As a result, the decrease of the core voltage VCORE is possible and the voltage level of the core voltage VCORE becomes stable in the auto refresh mode as well as the active mode.

In abovementioned embodiment, the over-drive control signal generator of the present invention includes the auto refresh mode delay controller and the pulse generator. Meanwhile, in another embodiment, it is also possible to include first and second pulse generators each of which receives the BLSA enable signal SAEN and have different delay lengths in an over-drive control signal generator. In this case, it is possible to vary the pulse length of the over-drive control signal in response to the auto refresh signal AREF by using the first and the second pulse generators. Further, in abovementioned embodiment, the normal driver drives the pull up power line RTO and the over-driver drives the core voltage VCORE terminal. In another embodiment, both the normal driver and the over-driver drive the pull up power line in parallel. Still further, in abovementioned embodiment, the present invention uses the core voltage VCORE as a normal drive voltage and the power supply voltage VDD as an over-drive voltage. In another embodiment, using the present invention, it is possible to use various voltages as the normal drive voltage and the over-drive voltage. Finally, the logic gates and transistors can be freely interchangeable and can be arranged in various ways according to a logic level of their input signals.

While the present invention has been described with respect to the specific embodiments, it will be apparent to those skilled in the art that various changes and modifications may be made without departing from the spirit and scope of the invention as defined in the following claims.

What is claimed is:

1. An over-drive control signal generator for use in a semiconductor memory device, comprising:
a pulse control unit configured to delay a bit line sense amplifier (BLSA) enable signal for a first delay time in response to an auto refresh signal to thereby output a delayed BLSA enable signal; and
a pulse generation unit configured to generate an over-drive control signal having a pulse length corresponding to an over-drive time by delaying the delayed BLSA enable signal for a second delay time in response to the BLSA enable signal.

2. The over-drive control signal generator as recited in claim 1, wherein the second delay time corresponds to an over-drive time required for an active mode.

3. The over-drive control signal generator as recited in claim 2, wherein the first delay time corresponds to a time subtracting the over-drive time required for the active mode from the over-drive time required for an auto refresh mode.

4. The over-drive control signal generator as recited in claim 3, wherein the delay control unit includes:
a first delay for delaying the BLSA enable signal for the first delay time;
a first inverter for inverting an output of the first delay;
a first NAND gate for logically combining an output of the first inverter and the auto refresh signal;
a second NAND gate for logically combining an output of the first NAND gate and the BLSA enable signal; and
a second inverter for inverting an output of the second NAND gate to thereby output the delayed BLSA enable signal.

5. The over-drive control signal generator as recited in claim 4, wherein the pulse generation unit includes:
a second delay for delaying the delayed BLSA enable signal for the second delay time;
a third inverter for inverting an output of the second delay; and
a third NAND gate for logically combining an output of the third inverter and the BLSA enable signal to thereby generate the over-drive control signal.

6. The over-drive control signal generator as recited in claim 3, wherein the delay control unit delays the BLSA enable signal for the first delay time when the auto refresh signal is active.

7. The over-drive control signal generator as recited in claim 6, wherein the delayed BLSA enable signal has substantially the same phase as the BLSA enable signal when the auto refresh signal is inactive.

8. The over-drive control signal generator as recited in claim 7, wherein the delay control unit includes:
a first delay for delaying the BLSA enable signal for the first delay time;
a first inverter for inverting an output of the first delay;
a first NAND gate for logically combining an output of the first inverter and the auto refresh signal;
a second NAND gate for logically combining an output of the first NAND gate and the BLSA enable signal; and
a second inverter for inverting an output of the second NAND gate to thereby output the delayed BLSA enable signal.

9. The over-drive control signal generator as recited in claim 8, wherein the pulse generation unit includes:
a second delay for delaying the delayed BLSA enable signal for the second delay time;
a third inverter for inverting an output of the second delay; and
a third NAND gate for logically combining an output of the third inverter and the BLSA enable signal to thereby generate the over-drive control signal.

10. A method for controlling an over-drive operation of a semiconductor memory device, comprising:
generating an over-drive control signal having a pulse length corresponding to a predetermined delay time in response to a bit line sense amplifier (BLSA) enable signal for an active mode;
generating the over-drive control signal having a pulse length longer than the predetermined delay time in response to the BLSA enable signal for an auto refresh mode; and
performing the over-drive operation in response to the over-drive control signal.

11. A method for controlling an over-drive operation of a semiconductor memory device, comprising:
performing a delay operation on a bit line sense amplifier (BLSA) enable signal for a first delay time in response to an auto refresh signal to thereby generate a delayed BLSA enable signal;
generating an over-drive control signal having a pulse length corresponding to an over-drive time by delaying the delayed BLSA enable signal for a second delay time in response to the BLSA enable signal; and
performing the over-drive operation in response to the over-drive control signal.

12. The method as recited in claim 11, wherein the second delay time corresponds to the over-drive time required for an active mode.

13. The method as recited in claim 12, wherein the first delay time corresponds to a time subtracting the over-drive time required for the active mode from the over-drive time required for an auto refresh mode.

14. The method as recited in claim 11, wherein the delayed BLSA enable signal has substantially the same phase as the BLSA enable signal when the auto refresh signal is inactive.

15. An over-drive control signal generator for use in a semiconductor memory device, comprising:
a pulse generation unit for generating an over-drive control signal by delaying a bit line sense amplifier (BLSA) enable signal in response to an auto refresh signal; and
a sense amplifier over-drive unit for performing an over-drive operation in response to the over-drive control signal.

16. The over-drive control signal generator as recited in claim 15, wherein the pulse generation unit includes:
a pulse control unit configured to delay the BLSA enable signal for a first delay time in response to the auto refresh signal to thereby output a delayed BLSA enable signal; and
a pulse generation unit configured to generate the over-drive control signal having a pulse length corresponding to an over-drive time by delaying the delayed BLSA enable signal for a second delay time in response to the BLSA enable signal.
